(19) United States
(12) Patent Application Publication
(10) Pub. No.: US 2024/0321972 A1
(43) Pub. Date: Sep. 26, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Shinya SATO, Nonoichi Ishikawa (JP)

(21) Appl. No.: 18/510,231

(22) Filed: Nov. 15, 2023

(30) Foreign Application Priority Data
Mar. 24, 2023 (JP) 2023-048689

(51) Int. Cl. H01L 29/32; H01L 21/22; H01L 27/06; H01L 29/06; H01L 29/739; H01L 29/861

(52) U.S. Cl. CPC H01L 29/32; H01L 21/221; H01L 27/0664; H01L 29/0623; H01L 29/7397; H01L 29/8613

(57) ABSTRACT

According to one embodiment, a semiconductor device includes a first electrode, a first semiconductor region of a first conductivity type, a first region, a second semiconductor region of a second conductivity type, and a second electrode. The first semiconductor region is located on the first electrode. The first region is located in the first semiconductor region. A concentration of carbon in the first region is greater than a concentration of carbon in the first semiconductor region. A concentration of a first element in the first region is greater than a concentration of the first element in the first semiconductor region. The first element is at least one selected from the group consisting of platinum, gold, iron, copper, and nickel. The second semiconductor region is located on the first semiconductor region. The second electrode is located on the second semiconductor region.

### CROSS-REFERENCE TO RELATED APPLICATIONS

This application is based upon and claims the benefit of priority from Japanese Patent Application No. 2023-048689, filed on Mar. 24, 2023; the entire contents of which are incorporated herein by reference.

### FIELD

Embodiments of the invention generally relate to a semiconductor device.

### BACKGROUND

Semiconductor devices such as diodes, insulated gate bipolar transistors (IGBTs), reverse conducting insulated gate bipolar transistors (RC-IGBTs), and the like are used in applications such as power conversion, etc. It is desirable to reduce the switching loss of these semiconductor devices.

### BRIEF DESCRIPTION OF THE DRAWINGS

FIG. 1 is a plan view showing a semiconductor device according to a first embodiment;

FIG. 2 is a plan view showing a semiconductor device according to the first embodiment;

FIG. 3 is an A1-A2 cross-sectional view of FIGS. 1 and 2;

FIG. 4 is a schematic view illustrating a concentration profile;

FIG. 5 is a schematic view illustrating characteristics of the semiconductor device according to the first embodiment;

FIGS. 6A and 6B are cross-sectional views showing a method for manufacturing the semiconductor device according to the first embodiment;

FIGS. 7A and 7B are cross-sectional views showing the method for manufacturing the semiconductor device according to the first embodiment;

FIG. 8 is a cross-sectional view showing a portion of a semiconductor device according to a modification of the first embodiment;

FIG. 9 is a cross-sectional view showing a portion of a semiconductor device according to a modification of the first embodiment;

FIG. 10 is a cross-sectional view showing a portion of a semiconductor device according to a modification of the first embodiment;

FIG. 11 is a cross-sectional view showing a portion of a semiconductor device according to a modification of the first embodiment;

FIG. 12 is a plan view showing a semiconductor device according to a second embodiment;

FIG. 13 is an A1-A2 cross-sectional view of FIG. 12;

FIG. 14 is a cross-sectional view showing a portion of a semiconductor device according to a modification of the second embodiment;

FIG. 15 is a cross-sectional view showing a portion of a semiconductor device according to a modification of the second embodiment;

FIG. 16 is a cross-sectional view showing a portion of a semiconductor device according to a modification of the second embodiment;

FIG. 17 is a cross-sectional view showing a portion of a semiconductor device according to a modification of the second embodiment;

FIG. 18 is a plan view showing a semiconductor device according to a third embodiment;

FIG. 19 is an A1-A2 cross-sectional view of FIG. 18;

FIG. 20 is a cross-sectional view showing a portion of a semiconductor device according to a modification of the third embodiment;

FIG. 21 a cross-sectional view showing a portion of a semiconductor device according to a modification of the third embodiment; and

FIG. 22 is a cross-sectional view showing a portion of a semiconductor device according to a modification of the third embodiment.

### DETAILED DESCRIPTION

According to one embodiment, a semiconductor device includes a first electrode, a first semiconductor region of a first conductivity type, a first region, a second semiconductor region of a second conductivity type, and a second electrode. The first semiconductor region is located on the first electrode. The first region is located in the first semiconductor region. A concentration of carbon in the first region is greater than a concentration of carbon in the first semiconductor region. A concentration of a first element in the first region is greater than a concentration of the first element in the first semiconductor region. The first element is at least one selected from the group consisting of platinum, gold, iron, copper, and nickel. The second semiconductor region is located on the first semiconductor region. The second electrode is located on the second semiconductor region.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

In the following description, the notations “n⁺”, “n” and “n⁻” and the notations “p⁺”, and “p” represent the relative levels of impurity concentrations of the conductivity types. Specifically, the notation “n+” indicates that the n-type impurity concentration is relatively higher than the notation “n”, and the notation “n⁻” indicates that the n-type impurity concentration is relatively lower than the notation “n”. The notation “p⁺” indicates that the p-type impurity concentration is relatively higher than the notation “p” The embodiments described below may be carried out with the p-type and the n-type of the semiconductor regions inverted.

An XYZ orthogonal coordinate system is used in the description of embodiments. The direction from a first electrode toward a first semiconductor region is taken as a Z-direction (a mutually-orthogonal directions first direction). Two perpendicular to the Z-direction are taken as an X-direction (a second direction) and a Y-direction (a third direction). In the description, the direction from the first electrode toward the first semiconductor region is called “up”, and the opposite direction is called “down”. These directions are based on the relative positional relationship between the first electrode and the first semiconductor region, and are independent of the direction of gravity.

### First Embodiment

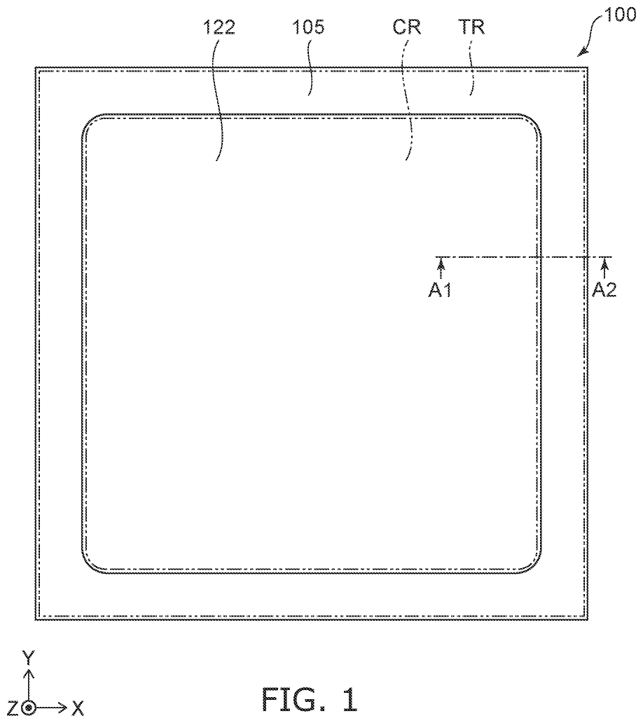

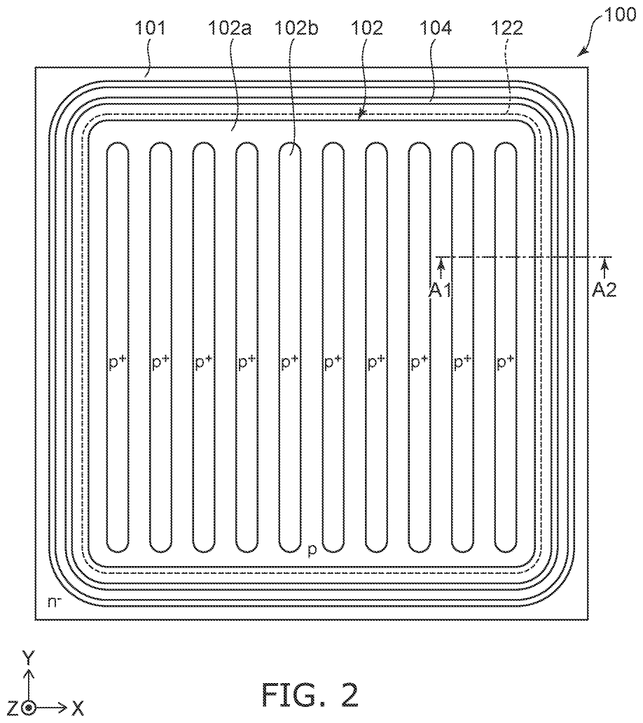

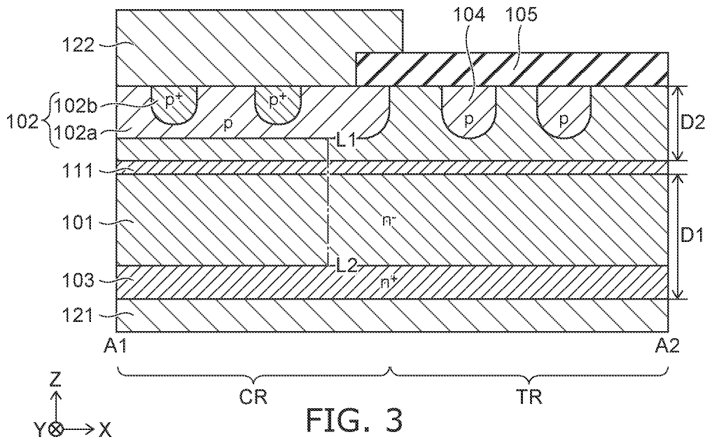

FIGS. 1 and 2 are plan views showing a semiconductor device according to a first embodiment. FIG. 3 is an A1-A2 cross-sectional view of FIGS. 1 and 2.

The semiconductor device according to the first embodiment is a diode. As shown in FIGS. 1 to 3, the semiconductor device 100 according to the first embodiment includes a cathode region 101 (an example of a first semiconductor region) of an n-type (an example of a first conductivity type), an anode region 102 (an example of a second semiconductor region) of a p-type (an example of a second conductivity type), a contact region 103, a guard ring region 104, an insulating layer 105, a first region 111, a cathode electrode 121 (an example of a first electrode), and an anode electrode 122 (an example of a second electrode). In FIG. 2, the insulating layer 105 is not illustrated, and the anode electrode 122 is illustrated by a broken line.

As shown in FIGS. 1 and 2, the anode electrode 122 is located at the upper surface of the semiconductor device 100. The upper surface of the semiconductor device 100 is covered with the insulating layer 105 at the periphery of the anode electrode 122. As shown in FIG. 3, the cathode electrode 121 is located at the lower surface of the semiconductor device 100. The contact region 103 is located on the cathode electrode 121 between the cathode electrode 121 and the anode electrode 122. The contact region 103 is electrically connected with the cathode electrode 121. The cathode region 101 is located on the 10 contact region 103. The n-type impurity concentration in the contact region 103 is higher than the n-type impurity concentration in the cathode region 101.

The anode region 102 is located on the cathode region 101. A p-n junction is formed between the cathode region 101 and the anode region 102. The anode region 102 includes a p-type semiconductor part 102a and a p⁺-type semiconductor part 102b. The p⁺-type semiconductor part 102b is located on at least a portion of the p-type semiconductor part 102a. The p-type impurity concentration of the p⁺-type semiconductor part 102b is greater than the p-type impurity concentration of the p-type semiconductor part 102a. The anode electrode 122 is located on the anode region 102 and is electrically connected with the anode region 102.

The guard ring region 104 is located around the anode region 102 along the X-Y plane. The guard ring region 104 is separated from the anode region 102. As illustrated, multiple guard ring regions 104 may be arranged toward the outer perimeter of the semiconductor device 100. The multiple guard ring regions 104 are separated from each other.

The first region 111 is located in the cathode region 101. The carbon concentration in the first region 111 is greater than the carbon concentration in the cathode region 101. The concentration of a first element in the first region 111 is greater than the concentration of the first element in the cathode region 101. The first element is at least one selected from the group consisting of platinum, gold, iron, copper, and nickel.

In the illustrated example, the first region 111 spreads along the X-Y plane. In other words, the Z-direction length of the first region 111 is less than the X-direction length of the first region 111 and less than the Y-direction length of the first region 111.

As shown in FIGS. 1 and 3, the semiconductor device 100 includes an element region CR, and a termination region TR located around the element region CR. The cathode regions 101 and 103 are located in the element region CR and the termination region TR. The anode region 102 is located in the element region CR. The guard ring region 104 is located in the termination region TR. The anode electrode 122 is located on the element region CR. For example, the first region 111 is located in both the element region CR and the termination region TR.

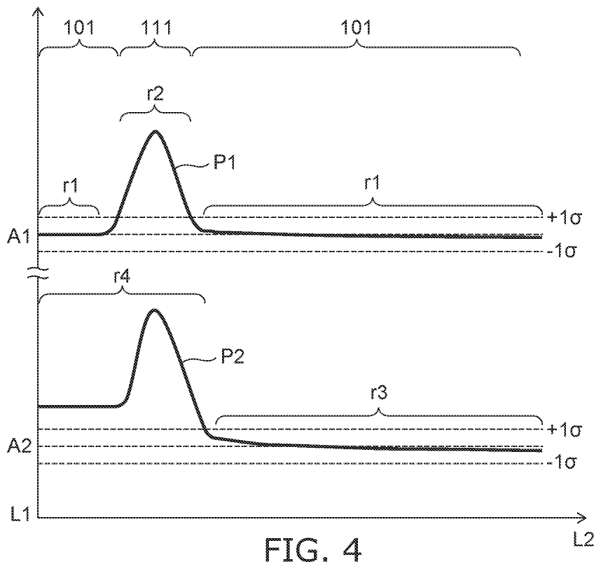

FIG. 4 is a schematic view illustrating a concentration profile.

FIG. 4 shows the concentration profile along line L1-L2 of FIG. 3. In FIG. 4, the horizontal axis is the Z-direction position, and the vertical axis is the concentration. A profile P1 shows the carbon concentration; and a profile P2 shows the concentration of the first element. When the elements included in the cathode region 101 are analyzed along the Z-direction as shown in FIG. 4, the region that has a higher concentration of carbon than the other regions and has a higher first element concentration than the other regions is identified as the first region 111.

For example, the first region 111 can be identified by the following method. The profiles of the carbon concentration and the first element concentration are acquired by analyzing the cathode region 101 in the Z-direction. Secondary ion mass spectrometry (SIMS), cathodoluminescence, photoluminescence spectroscopy, or deep level transient spectroscopy (DLTS) is used for the analysis. In cathodoluminescence, photoluminescence spectroscopy, and DLTS, signals are observed at specific energy levels (crystal defects) formed by the first element and carbon. In DLTS, the crystal defect concentration is measured. The signal intensity profile obtained by cathodoluminescence or photoluminescence spectroscopy and the crystal defect concentration profile obtained by DLTS correspond to the element concentration profile. The method for identifying the first region 111 in an element concentration profile measured by SIMS will be described herein. When cathodoluminescence or photoluminescence spectroscopy is used, “concentration profile” in the following description should be read as “signal intensity profile”. When DLTS is used, “concentration profile” corresponds to the crystal defect concentration profile.

First, a region of low concentration in the carbon profile is identified. The “region of low concentration” is the region that is below the detection limit. Regions in the carbon profile in which the carbon concentration increases above the detection limit are identified. When the carbon concentration is greater than the detection limit in any region, a histogram of the carbon concentration in the Z-direction is acquired for each semiconductor region between the cathode electrode 121 and the anode electrode 122. The population that has the lowest concentration is identified as the “region of low concentration”. In such a case, the average value and the standard deviation σ of the region of low concentration are calculated. The regions in which the carbon concentration increases above the average value ±1σ are identified.

Similarly, in the first element concentration profile, the region that is below the detection limit is identified as the “region of low concentration”; and the regions in which the first element concentration increases above the detection limit are identified. When the first element concentration is greater than the detection limit in any region, a histogram of the first element concentration in the Z-direction is acquired for each semiconductor region between the cathode electrode 121 and the anode electrode 122. The population that has the lowest concentration is identified as the “region of low concentration”. In such a case, the average value and the standard deviation of the region of low concentration are calculated. The regions in which the first element concentration increases above the concentration average value ±1σ are identified. The region in which the carbon concentration increases and the first element concentration increases is determined to be the first region 111.

In the example shown in FIG. 4, a region r1 in which the carbon concentration is low is identified in the carbon concentration profile. An average value A1 and a standard deviation σ of the concentration in the region r1 are calculated. A region r2 that is greater than the average value A1±1σ is identified. Similarly, a region r3 in which the first element concentration is low is identified in the first element concentration profile. An average value A2 and a standard deviation σ of the concentration in the region r3 are calculated. A region r4 that is greater than the average value A2±1σ is identified. The region that is included in both the regions r2 and r4 is identified as the first region 111.

As shown in FIG. 4, in the region in which the carbon concentration is high, the first element concentration also is high. In other words, it can be seen from the concentration profile that carbon has a gettering effect for the first element.

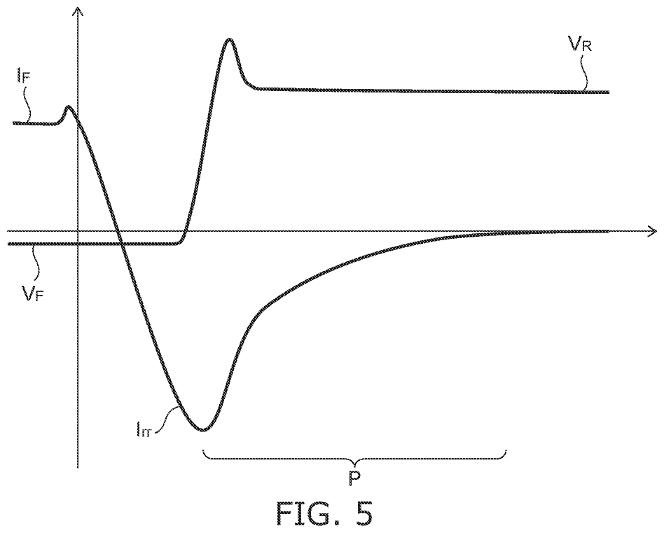

FIG. 5 is a schematic view illustrating characteristics of the semiconductor device according to the first embodiment.

In FIG. 5, the horizontal axis is time. The vertical axis is the current or voltage. In FIG. 5, the positive side of the vertical axis shows a state in which a positive voltage with respect to the anode electrode 122 is applied to the cathode electrode 121, or a state in which a current flows from the anode electrode 122 toward the cathode electrode 121. The negative side of the vertical axis shows a state in which a positive voltage with respect to the cathode electrode 121 is applied to the anode electrode 122, or a state in which a current flows from the cathode electrode 121 toward the anode electrode 122.

When a positive voltage V_{F} with respect to the cathode electrode 121 is applied to the anode electrode 122, a forward voltage is applied to the p-n diode formed from the cathode region 101 and the anode region 102. As a result, a forward current IF flows from the cathode region 101 to the anode region 102. In other words, the semiconductor device 100 is set to the on-state. At this time, carriers accumulate in the cathode region 101; and the electrical resistance of the cathode region 101 decreases. In this situation, a reverse voltage V_{R} is applied to the semiconductor device 100, the carriers that accumulated in the cathode region 101 are discharged to the cathode electrode 121 and the anode electrode 122. As a result, a recovery current Iᵣᵣ flows from the cathode region 101 to the anode region 102.

Examples of the materials of the components will now be described.

The cathode region 101, the anode region 102, the contact region 103, and the guard ring region 104 include silicon, silicon carbide, gallium nitride, or gallium arsenide as a semiconductor material. When silicon is used as the semiconductor material, arsenic, phosphorus, or antimony can be used as an n-type impurity. Boron can be used as a p-type impurity. The cathode electrode 121 and the anode electrode 122 include metals such as titanium, aluminum, etc.

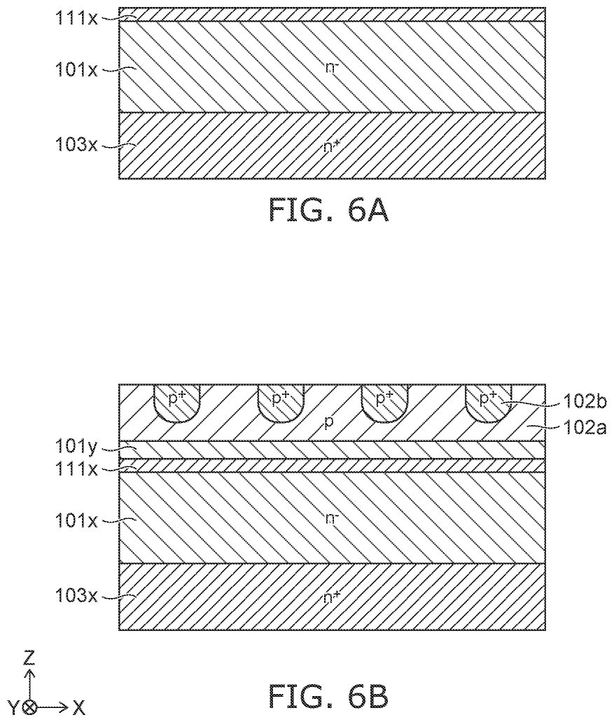

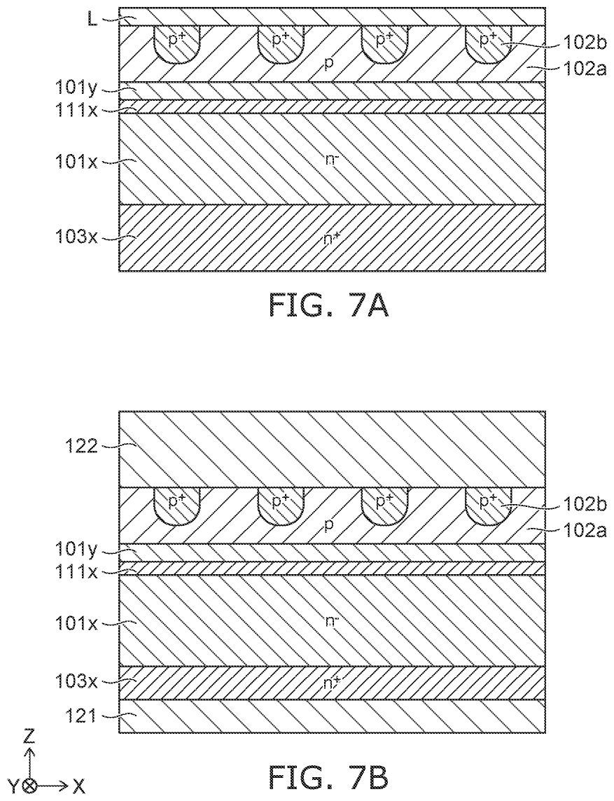

FIGS. 6A, 6B, 7A, and 7B are cross-sectional views showing a method for manufacturing the semiconductor device according to the first embodiment.

First, a semiconductor substrate that includes an n⁻-type semiconductor layer 101x and an n⁺-type semiconductor layer 103x is prepared. The n-type semiconductor layer 101x is located on the n⁺-type semiconductor layer 103x. Carbon is ion-implanted into the surface of the n⁻-type semiconductor layer 101x. For example, ion implantation is performed so that the impurity concentration peak of carbon is positioned at the surface of the n⁻-type semiconductor layer 101x. Carbon is ion-implanted into the region at which the first region 111 will be formed. A mask may be formed on the n⁻-type semiconductor layer 101x when the first region 111 is formed in only a portion of the cathode region 101 in the X-Y plane. The region at which the first region 111 will be subsequently formed can be controlled by ion-implanting carbon into the region at which the mask is not formed. As shown in FIG. 6A, a region 111x that has a higher carbon concentration than the surrounding regions is formed by ion implantation.

An n⁻-type semiconductor layer 101y is formed by epitaxially growing a semiconductor material on the n⁻-type semiconductor layer 101x and the region 111x. The p-type semiconductor part 102a is formed as shown in FIG. 6B by ion-implanting a p-type impurity into the surface of the n-type semiconductor layer 101y.

The p⁺-type semiconductor part 102b is formed by ion-implanting a p-type impurity into a portion of the surface of the p-type semiconductor part 102a. As shown in FIG. 7A, a layer L that includes the first element is formed on the p-type semiconductor part 102a and the p⁺-type semiconductor part 102b. The first element that is included in the layer L is diffused by heat treatment toward the n⁻-type and n-type semiconductor layers 101x and 101y. The diffused first element bonds with the carbon of the region 111x. The region 111x thereby has a higher first element concentration than the surrounding regions.

The anode electrode 122 is formed by sputtering a metal material on the p-type semiconductor part 102a and the p⁺-type semiconductor part 102b. The back surface of the n⁺-type semiconductor layer 103x is grinded until the n⁺-type semiconductor layer 103x has a prescribed thickness. As shown in FIG. 7B, the cathode electrode 121 is formed by sputtering a metal material on the back surface of the n⁺-type semiconductor layer 103x. Thus, the semiconductor device 100 according to the first embodiment is manufactured.

Advantages of the first embodiment will now be described.

As shown in FIG. 5, the recovery current Iᵣᵣ flows when the semiconductor device 100 is switched to the off-state. It is favorable for the recovery current Iᵣᵣ to be small. As the recovery current Iᵣᵣ is reduced (near zero), the switching of the semiconductor device 100 can be faster, and the switching loss of the semiconductor device 100 can be reduced. To reduce the recovery current Iᵣᵣ, it is effective for the cathode region 101 to include the first element. The first element functions as a lifetime killer that reduces the carrier lifetime. By reducing the carrier lifetime, the first element can reduce the recovery current Iᵣᵣ and reduce the switching loss of the semiconductor device 100.

It is favorable for the first element to exist locally. The recovery current Iᵣᵣ can be reduced even when the first element spreads to the entire cathode region 101. However, in such a case, the density of the carriers accumulated in the cathode region 101 when the semiconductor device 100 is in the on-state also is reduced. As a result, the on-resistance of the semiconductor device 100 increases. Because the first element exists locally, the recovery current Iᵣᵣ can be reduced while suppressing the increase of the on-resistance.

Conventionally, the first element is ion-implanted to the prescribed depth of the cathode region 101 so that the first element exists locally. In such a case, ions are implanted into the cathode region 101 and the anode region 102 with high energy, and crystal defects of these regions are increased. As a result, the leakage current when the semiconductor device 100 is in the off-state increases. There is also a method in which the occurrence of crystal defects is suppressed by diffusing the first element to the cathode region 101 from a layer including the first element. However, according to this method, it is difficult for the first element to exist locally because the first element diffuses uniformly toward the cathode region 101.

For this problem, carbon is included in a specific region of the cathode region 101 in the semiconductor device 100 according to the first embodiment. The carbon has a gettering effect for metal atoms such as platinum, gold, iron, copper, nickel, etc., with point defects such as interstitial silicon and atomic vacancies. Therefore, when the first element is diffused into the cathode region 101, much of the first element collects in the region including carbon due to the gettering by the carbon. The carbon functions as a gettering element for the first element. As a result, compared to the surrounding regions, the first region 111 that has a higher carbon concentration and a higher first element concentration is formed in the cathode region 101. Carbon is electrically neutral.

Crystal defects of the cathode region 101 can be suppressed because the first region 111 can be formed by ion-implanting carbon into a shallow position and by diffusing the first element. The increase of the leakage current can be suppressed thereby. Also, carbon is electrically neutral. Therefore, the first region 111 substantially does not affect the leakage current. By providing the first region 111 in which the first element concentration is locally high, the switching loss of the semiconductor device 100 can be reduced while suppressing the increase of the on-resistance of the semiconductor device 100.

For example, the first region 111 is located in the cathode region 101 and is positioned at the anode electrode 122 side. In other words, as shown in FIG. 3, a distance D2 in the Z-direction between the anode electrode 122 and the first region 111 is less than a distance D1 in the Z-direction between the cathode electrode 121 and the first region 111. When the first region 111 is formed at the anode electrode 122 side, compared to when the first region 111 is formed at the center of the cathode region 101, the recovery current Iᵣᵣ can be further reduced while reducing the on-resistance of the semiconductor device 100.

Platinum is most favorable as the first element. The generation lifetime and the lifetime at low injection levels are indicators of the performance as a lifetime killer. As the generation lifetime decreases, electron-hole pairs are more easily generated, which may cause leakage current. The switching speed of the device increases as the low injection lifetime decreases. That is, it is desirable for a ratio τsc/τLL to be large, where τsc is the space-charge-generation lifetime at low injection levels, and τLL is the low injection lifetime. The platinum has a high τsc/τLL value. For example, the τsc/τLL value of platinum is not less than 100 times the τsc/τLL value of gold at room temperature. Platinum has a higher τsc/τLL value than that of an electron beam irradiation technique which is widely used. Therefore, compared to when the first element other than Pt is used or when electron beam irradiation is used, platinum has excellent performance as a lifetime control factor.

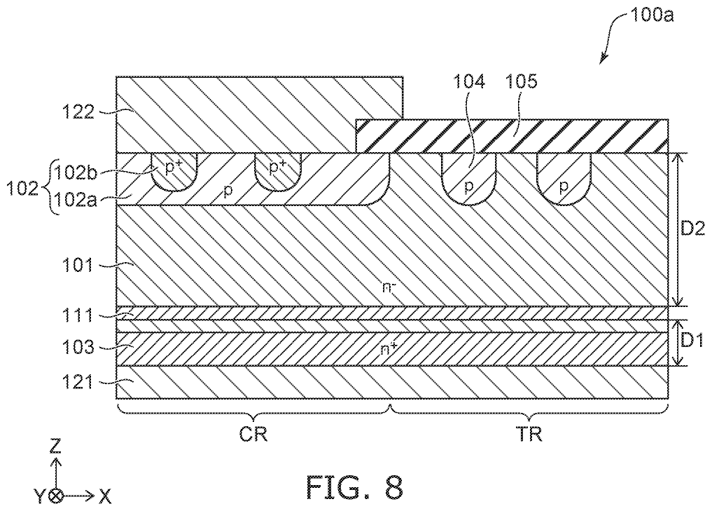

FIGS. 8 to 11 are cross-sectional views showing portions of semiconductor devices according to modifications of the first embodiment.

As in a semiconductor device 100a shown in FIG. 8, the first region 111 may be positioned at the cathode electrode 121 side. In other words, the distance D1 between the cathode electrode 121 and the first region 111 is less than the distance D2 between the anode electrode 122 and the first region 111. When the first region 111 is formed at the cathode electrode 121 side, compared to when the first region 111 is formed at the center of the cathode region 101, an attenuation period P of the recovery current Iᵣᵣ (shown in FIG. 5) can be further reduced while reducing the on-resistance of the semiconductor device 100a. The switching loss of the semiconductor device 100a can be reduced thereby.

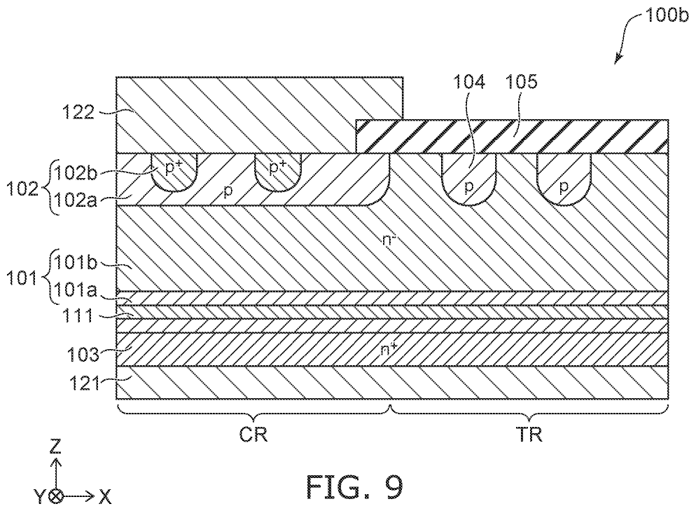

In a semiconductor device 100b shown in FIG. 9, the cathode region 101 includes an n-type semiconductor part 101a (an example of a first part) and an n′-type semiconductor part 101b (an example of a second part). The n-type semiconductor part 101b is located on the n-type semiconductor part 101a. The n-type impurity concentration in the n-type semiconductor part 101a is less than the n-type impurity concentration in the contact region 103. The n-type impurity concentration in the n⁻-type semiconductor part 101b is less than the n-type impurity concentration in the n-type semiconductor part 101a.

The first region 111 is located in the n-type semiconductor part 101a. Because the n-type impurity concentration in the n-type semiconductor part 101a is greater than the n-type impurity concentration in the n⁻-type semiconductor part 101b, the n-type semiconductor part 101a is not completely depleted when the semiconductor device 100b is in the off-state. In other words, the depletion layer does not reach the first region 111 inside the n-type semiconductor part 101a. The first region 111 includes a small amount of crystal defects generated when ion-implanting carbon. By providing the first region 111 in a region not reached by the depletion layer, the leakage current of the semiconductor device 100b can be further reduced while reducing the switching loss of the semiconductor device 100b.

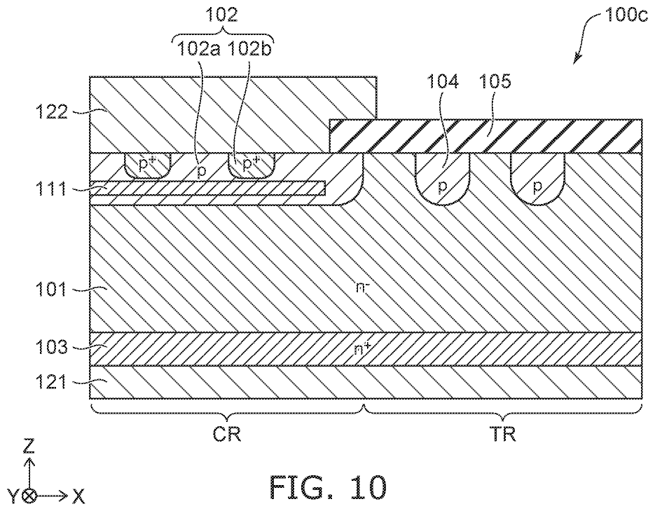

As in a semiconductor device 100c shown in FIG. 10, the first region 111 may be located in the p-type semiconductor part 102a. In such a case, the carbon concentration in the first region 111 is greater than the carbon concentration in the anode region 102. The first element concentration in the first region 111 is greater than the first element concentration in the anode region 102. When the elements included in the anode region 102 are analyzed along the Z-direction, the region having a higher carbon concentration than the other regions and having a higher first element concentration than the other regions is identified as the first region 111.

The p-type impurity concentration in the p-type semiconductor part 102a is greater than the n-type impurity concentration in the n⁻-type semiconductor part 101b. Therefore, when the semiconductor device 100c is in the off-state, the depletion layer does not spread easily in the p-type semiconductor part 102a compared to the n-type semiconductor part 101b. By providing the first region 111 in a region of the p-type semiconductor part 102a that is undepleted, the leakage current of the semiconductor device 100c can be further reduced while reducing the switching loss of the semiconductor device 100c.

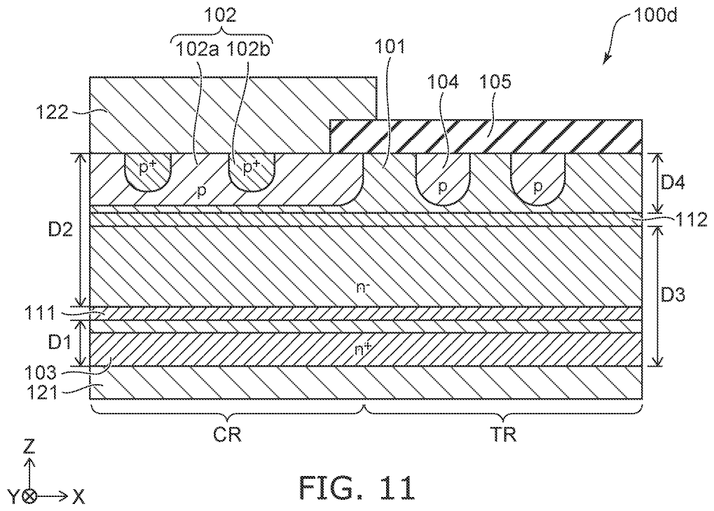

As in a semiconductor device 100d shown in FIG. 11, a second region 112 may be provided in addition to the first region 111. The second region 112 is located in the cathode region 101. The carbon concentration in the second region 112 is greater than the carbon concentration in the cathode region 101. The first element concentration in the second region 112 is greater than the first element concentration in the cathode region 101. The Z-direction length of the second region 112 is less than the X-direction length of the second region 112 and less than the Y-direction length of the second region 112.

The second region 112 is separated from the first region 111 in the Z-direction. The first region 111 is located at the cathode electrode 121 side. The second region 112 is located at the anode electrode 122 side. In other words, the distance D1 in the Z-direction between the cathode electrode 121 and the first region 111 is less than the distance D2 in the Z-direction between the anode electrode 122 and the first region 111. A distance D3 in the Z-direction between the cathode electrode 121 and the second region 112 is greater than a distance D4 in the Z-direction between the anode electrode 122 and the second region 112.

The second region 112 is formed by a method similar to that of the first region 111. Namely, carbon is doped (for example, ion-implanted) into the region at which the second region 112 is to be formed partway through the formation of the n⁻-type semiconductor layer. Subsequently, the first region 111 and the second region 112 are formed when diffusing the first element by the first element collecting in the region into which the carbon is doped.

By providing both the first and second regions 111 and 112, the switching loss can be further reduced compared to the semiconductor device 100 or the semiconductor devices 100a to 100c.

Appropriate combinations of the structures according to the modifications described above can be performed. For example, in the semiconductor device 100d, the first region 111 may be located in the n-type semiconductor part 101a. The second region 112 may be located in the p-type semiconductor part 102a.

### Second Embodiment

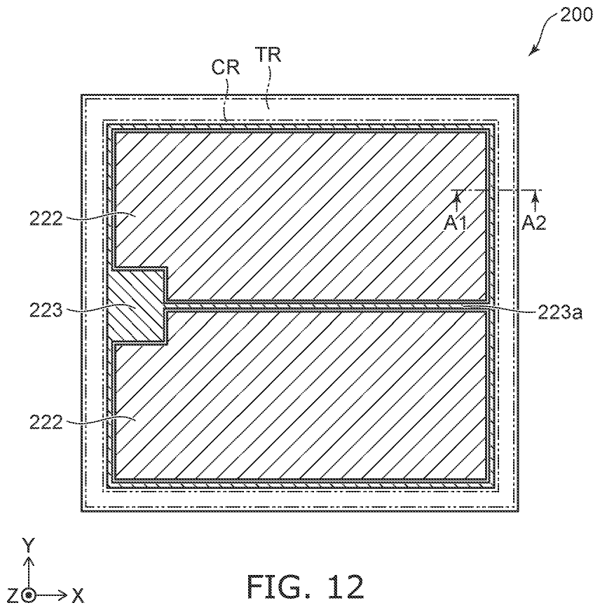

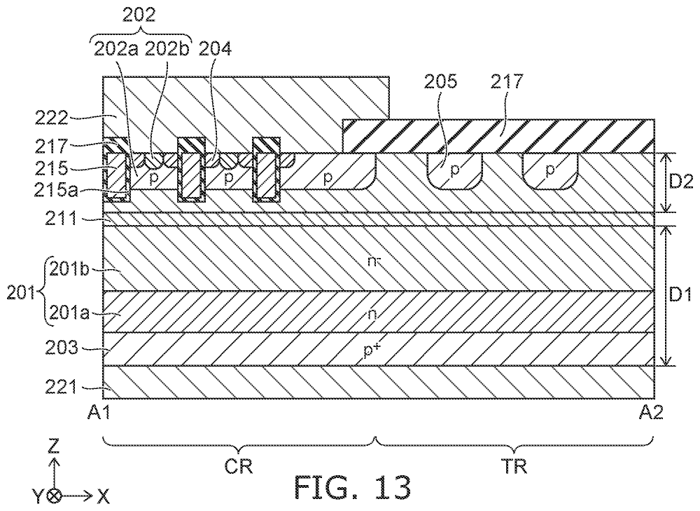

FIG. 12 is a plan view showing a semiconductor device according to a second embodiment. FIG. 13 is an A1-A2 cross-sectional view of FIG. 12.

The semiconductor device according to the second embodiment is an IGBT. As shown in FIGS. 12 and 13, the semiconductor device 200 according to the second embodiment includes an n-type base region 201 (an example of the first semiconductor region), a p-type base region 202 (an example of the second semiconductor region), a collector region 203 (an example of the third semiconductor region), an emitter region 204 (an example of a fourth semiconductor region), a first region 211, a gate electrode 215, a collector electrode 221 (an example of the first electrode), an emitter electrode 222 (an example of the second electrode), and a gate pad 223.

As shown in FIG. 12, the emitter electrode 222 and the gate pad 223 are located at the upper surface of the semiconductor device 200. The emitter electrode 222 and the gate pad 223 are separated from each other. In the illustrated example, multiple emitter electrodes 222 are provided, and a gate wiring part 223a is provided around the emitter electrodes 222. The gate wiring part 223a is electrically connected with the gate pad 223.

As shown in FIG. 13, the collector electrode 221 is located at the lower surface of the semiconductor device 200. The collector region 203 is located on the collector electrode 221 and is electrically connected with the collector electrode 221. The n-type base region 201 is located on the collector region 203. The n-type base region 201 may include an n-type semiconductor part 201a (an example of the first part) and an n⁻-type semiconductor part 201b (an example of the second part). The n-type semiconductor part 201b is located on the n-type semiconductor part 201a. The n-type impurity concentration in the n⁻-type semiconductor part 201b is less than the n-type impurity concentration in the n-type semiconductor part 201a.

The p-type base region 202 is located on the n-type base region 201. The emitter region 204 is located on the p-type base region 202. The p-type base region 202 may include a p-type semiconductor part 202a and a p⁺-type semiconductor part 202b. The p⁺-type semiconductor part 202b is located on the p-type semiconductor part 202a and is arranged with the emitter region 204 in the X-direction. The p-type impurity concentration in the p⁺-type semiconductor part 202b is greater than the p-type impurity concentration in the p-type semiconductor part 202a. The p-type base region 202 and the emitter region 204 are electrically connected with the emitter electrode 222.

A guard ring region 205 is located around the p-type base region 202 along the X-Y plane. The guard ring region 205 is separated from the p-type base region 202. As illustrated, multiple guard ring regions 205 may be provided toward the outer perimeter of the semiconductor device 200. The multiple guard ring regions 205 are separated from each other.

The gate electrode 215 faces the p-type semiconductor part 202a via a gate insulating layer 215a in the X-direction. An insulating layer 217 is located between the gate electrode 215 and the emitter electrode 222. The gate electrode 215 and the emitter electrode 222 are electrically isolated from each other.

Pluralities of the p-type base regions 202, the emitter regions 204, and the gate electrodes 215 are arranged in the X-direction. The p-type base regions 202, the emitters region 204, and the gate electrodes 215 are provided in stripe shapes and extend in the Y-direction. The Y-direction end portions of the gate electrodes 215 are connected with the gate wiring part 223a. The gate electrodes 215 are electrically connected with the gate pad 223 via the gate wiring part 223a.

The first region 211 is located in the n⁻-type semiconductor part 201b. Similarly to the semiconductor device according to the first embodiment, the carbon concentration in the first region 211 is greater than the carbon concentration in the n-type base region 201. The first element concentration in the first region 211 is greater than the first element concentration in the n-type base region 201. The first region 211 spreads along the X-Y plane. For example, the distance D2 in the Z-direction between the emitter electrode 222 and the first region 211 is less than the distance D1 in the Z-direction between the collector electrode 221 and the first region 211.

The method for identifying the first region 211 in the n-type base region 201 is similar to the method for identifying the first region 111 according to the first embodiment. Namely, the concentration profiles of carbon and the first element are obtained by analyzing the elements included in the n-type base region 201 along the Z-direction. The region in which the carbon concentration is low and the region in which the first element concentration is low are identified in the concentration profiles. The region in which the carbon concentration increases and the first element concentration increases with respect to the regions in which the concentrations are low are identified as the first region 211.

As shown in FIGS. 12 and 13, the semiconductor device 200 includes the element region CR, and the termination region TR located around the element region CR. The n-type base region 201 and the collector region 203 are located in the element region CR and the termination region TR. The p-type base region 202 and the emitter region 204 are located in the element region CR. The guard ring region 205 is located in the termination region TR. The emitter electrode 222 is located on the element region CR. For example, the first region 211 is located in both the element region CR and the termination region TR.

Operations of the semiconductor device 200 will now be described.

A voltage that is not less than a threshold is applied to the gate electrode 215 in a state in which a positive voltage with respect to the emitter electrode 222 is applied to the collector electrode 221. A channel (an inversion layer) is thereby formed in the p-type semiconductor part 202a. Electrons flow from the emitter region 204 to the n-type semiconductor part 201b via the channel; and holes flow from the collector region 203 toward the n′-type semiconductor part 201b. The density of the carriers accumulated in the n⁻-type semiconductor part 201b increases, and conductivity modulation occurs. The electrical resistance of the n⁻-type semiconductor part 201b is greatly reduced thereby, and the semiconductor device 200 is set to the on-state. Subsequently, when the voltage applied to the gate electrode 215 drops below the threshold, the channel in the p-type semiconductor part 202a disappears, and the semiconductor device 200 is switched to the off-state. When the semiconductor device 200 is switched to the off-state, the carriers that accumulated in the n⁻-type semiconductor part 201b are discharged to the collector electrode 221 and the emitter electrode 222.

Examples of the materials of the components will now be described.

The n-type base region 201, the p-type base region 202, the collector region 203, the emitter region 204, and the guard ring region 205 include silicon, silicon carbide, gallium nitride, or gallium arsenide as a semiconductor material. The gate electrode 215 includes polysilicon. The gate insulating layer 215a and the insulating layer 217 include insulating materials such as silicon oxide, silicon nitride, etc. The collector electrode 221, the emitter electrode 222, the gate pad 223, and the gate wiring part 223a include metals such as titanium, aluminum, etc.

Advantages of the second embodiment will now be described.

When the semiconductor device 200 is switched to the off-state, the carriers that accumulated in the n-type semiconductor part 201b are discharged to the collector electrode 221 and the emitter electrode 222. At this time, the switching loss of the semiconductor device 200 can be reduced by discharging the carriers more quickly. According to the second embodiment, similarly to the first embodiment, the first region 211 is provided in which the first element concentration is locally high. Therefore, according to the second embodiment, the switching loss of the semiconductor device 200 can be reduced while reducing the leakage current of the semiconductor device 200.

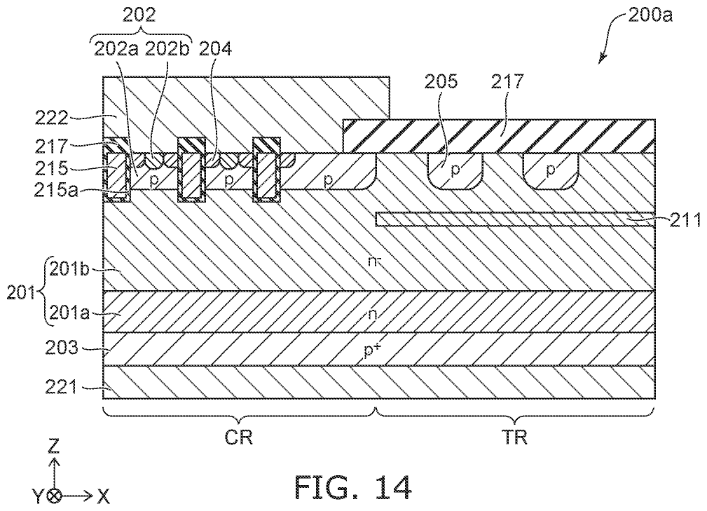

FIGS. 14 to 17 are cross-sectional views showing portions of semiconductor devices according to modifications of the second embodiment.

In a semiconductor device 200a shown in FIG. 14, the first region 211 is located in only the termination region TR. In the element region CR, a portion of the n-type base region 201 is located at the height (the Z-direction position) at which the first region 211 is located in the termination region TR. Therefore, the carbon concentration of the portion of the n-type base region 201 of the element region CR is less than the carbon concentration of the first region 211 of the termination region TR. The first element concentration of the portion of the n-type base region 201 of the element region CR is less than the first element concentration of the first region 211 of the termination region TR.

When the semiconductor device 200a is switched to the off-state, the carriers that accumulated in the termination region TR collect and are discharged at the p-type base region 202 at the outer perimeter of the element region CR. Therefore, a larger current flows in the p-type base region 202 at the outer perimeter of the element region CR than in the p-type base region 202 at the center of the element region CR. By providing the first region 211 in the termination region TR, the lifetime of the carriers accumulated in the termination region TR can be reduced, and the current that flows toward the p-type base region 202 at the outer perimeter of the element region CR at turn-off can be reduced. The likelihood of breakdown of the semiconductor device 200a can be reduced thereby. By not providing the first region 211 in the element region CR, the carrier density when the semiconductor device 200a is in the on-state can be increased, and the on-resistance of the semiconductor device 200a can be reduced.

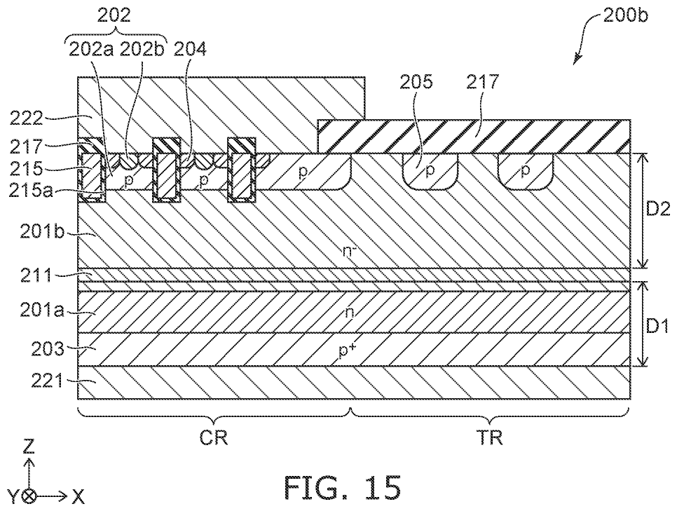

As in a semiconductor device 200b shown in FIG. 15, the first region 211 may be positioned at the collector electrode 221 side. In other words, the distance D1 between the collector electrode 221 and the first region 211 is less than the distance D2 between the emitter electrode 222 and the first region 211. According to the semiconductor device 200b, similarly to the semiconductor device 200, the switching loss can be reduced.

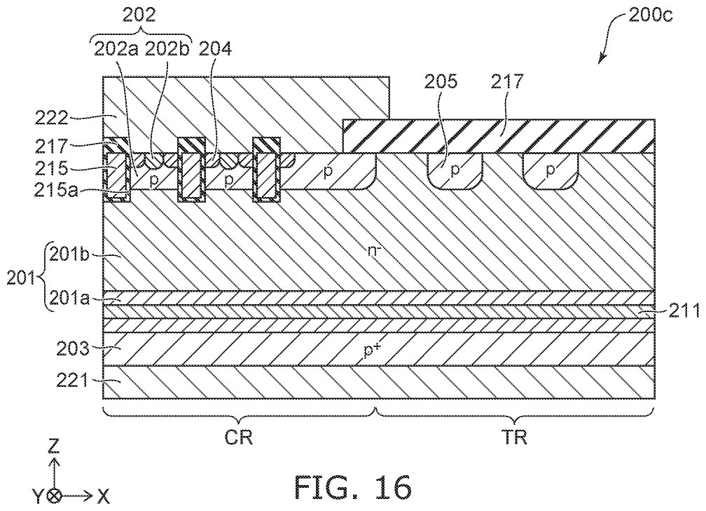

As in a semiconductor device 200c shown in FIG. 16, the first region 211 may be located in the n-type semiconductor part 201a. The n-type semiconductor part 201a is not completely depleted when the semiconductor device 200c is in the off-state. The first region 211 is located at a position not reached by the depletion layer. According to the semiconductor device 200c, compared to the semiconductor device 200b, the leakage current can be further reduced.

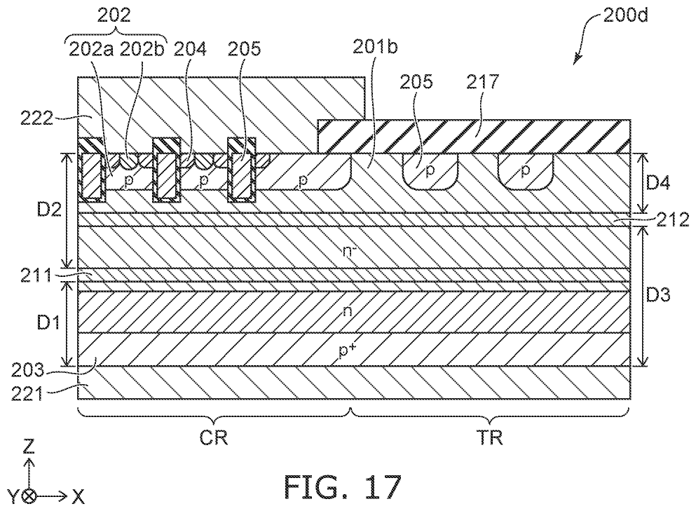

As in a semiconductor device 200d shown in FIG. 17, a second region 212 may be provided in addition to the first region 211. The second region 212 is located in the n-type base region 201. The carbon concentration in the second region 212 is greater than the carbon concentration in the n-type base region 201. The first element concentration in the second region 212 is greater than the first element concentration in the n-type base region 201. The Z-direction length of the second region 212 is less than the X-direction length of the second region 212 and less than the Y-direction length of the second region 212.

The second region 212 is separated from the first region 211 in the Z-direction. The first region 211 is located at the collector electrode 221 side. The second region 212 is located at the emitter electrode 222 side. In other words, the distance D1 in the Z-direction between the collector electrode 221 and the first region 211 is less than the distance D2 in the Z-direction between the emitter electrode 222 and the first region 211. The distance D3 in the Z-direction between the collector electrode 221 and the second region 212 is greater than the distance D4 in the Z-direction between the emitter electrode 222 and the second region 212.

By providing the second region 212 in addition to the first region 211, the switching loss of the semiconductor device 200d can be further reduced.

### Third Embodiment

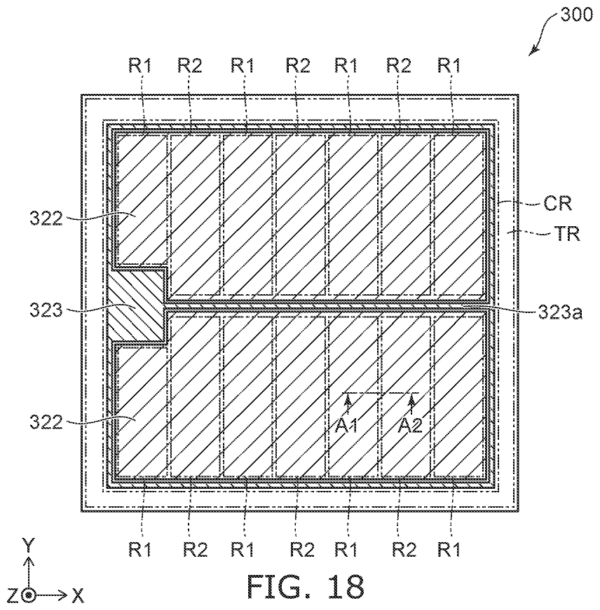

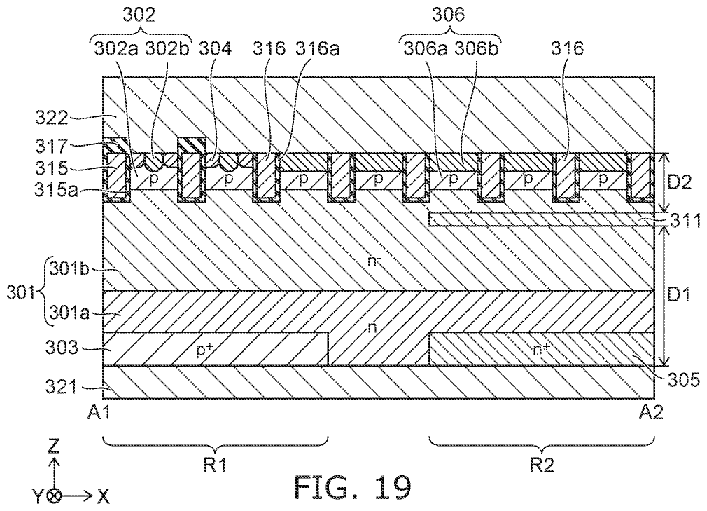

FIG. 18 is a plan view showing a semiconductor device according to a third embodiment. FIG. 19 is an A1-A2 cross-sectional view of FIG. 18.

The semiconductor device according to the third embodiment is an RC-IGBT. As shown in FIGS. 18 and 19, the semiconductor device 300 according to the third embodiment includes an n-type base region 301 (an example of the first semiconductor region), a p-type base region 302 (an example of the second semiconductor region), a collector region 303 (an example of the third semiconductor region), an emitter region 304 (an example of the fourth semiconductor region), a cathode region 305 (an example of a fifth semiconductor region), an anode region 306 (an example of a sixth semiconductor region), a first region 311, a gate electrode 315, a conductive part 316, an insulating layer 317, a collector electrode 321, an emitter electrode 322, and a gate pad 323.

For example, the structure of the collector electrode 321, the emitter electrode 322, the gate pad 323, and a gate wiring part 323a of the semiconductor device 300 is similar to the structure of the collector electrode 221, the emitter electrode 222, the gate pad 223, and the gate wiring part 223a of the semiconductor device 200. The semiconductor device 300 also includes an IGBT region R1 and a diode region R2. In the example shown in FIG. 18, multiple IGBT regions R1 and multiple diode regions R2 are arranged in the X-direction and the Y-direction.

As shown in FIG. 19, the IGBT region R1 includes the p-type base region 302, the collector region 303, the emitter region 304, the gate electrode 315, and a portion of the n-type base region 301.

The collector region 303 is located on a portion of the collector electrode 321. A portion of the n-type base region 301 is located on the collector region 303. The n-type base region 301 may include an n-type semiconductor part 301a (an example of the first part) and an n-type semiconductor part 301b (an example of the second part). The n-type semiconductor part 301b is located on the n-type semiconductor part 301a. The n-type impurity concentration in the n-type semiconductor part 301b is less than the n-type impurity concentration in the n-type semiconductor part 301a.

The p-type base region 302 is located on the portion of the n-type base region 301. The emitter region 304 is located on the p-type base region 302. The p-type base region 302 may include a p-type semiconductor part 302a and a p⁺-type semiconductor part 302b. The p⁺-type semiconductor part 302b is located on the p-type semiconductor part 302a and is arranged with the emitter region 304 in the X-direction. The p-type impurity concentration in the p⁺-type semiconductor part 302b is greater than the p-type impurity concentration in the p-type semiconductor part 302a. The gate electrode 315 faces the p-type semiconductor part 302a via a gate insulating layer 315a in the X-direction.

Pluralities of the p-type base regions 302, the emitter regions 304, and the gate electrodes 315 are arranged in the X-direction. The p-type base regions 302, the emitters region 304, and the gate electrodes 315 are provided in stripe shapes and extend in the Y-direction. The Y-direction end portions of the gate electrodes 315 are connected with the gate wiring part 323a. As shown in FIG. 19, some of the gate electrodes 315 in the IGBT region R1 may be replaced with the conductive part 316. In such a case, the conductive part 316 faces the p-type semiconductor part 302a via an insulating layer 316a in the X-direction.

The diode region R2 includes the cathode region 305, the anode region 306, the first region 311, the conductive part 316, and another portion of the n-type base region 301.

The cathode region 305 is located on another portion of the collector electrode 321. The n-type impurity concentration in the cathode region 305 is greater than the n-type impurity concentration in the n-type base region 301. Another portion of the n-type base region 301 is located on the cathode region 305. The anode region 306 is located on the other portion of the n-type base region 301.

The anode region 306 may include a p-type semiconductor part 306a and a p⁺-type semiconductor part 306b. The p⁺-type semiconductor part 306b is located on the p-type semiconductor part 306a and is arranged with the emitter region 304 in the X-direction. The p-type impurity concentration in the p⁺-type semiconductor part 306b is greater than the p-type impurity concentration in the p-type semiconductor part 306a. The conductive part 316 faces the p-type semiconductor part 306a via the insulating layer 316a in the X-direction.

Multiple anode regions 306 and multiple conductive parts 316 are arranged in the X-direction. For example, the anode regions 306 and the conductive parts 316 are provided in stripe shapes and extend in the Y-direction. Or, the conductive part 316 may be omitted from the diode region R2. In such a case, for example, similarly to the semiconductor device 100, one anode region 306 is provided on the n-type base region 301.

The emitter electrode 322 is located on the IGBT region R1 and the diode region R2. The emitter electrode 322 is positioned on the p-type base region 302, the emitter region 304, the anode region 306, the gate electrode 315, and the conductive part 316. The emitter electrode 322 is electrically connected with the p-type base region 302, the emitter region 304, the anode region 306, and the conductive part 316. The insulating layer 317 is located between the gate electrode 315 and the emitter electrode 322; and the gate electrode 315 and the emitter electrode 322 are electrically isolated from each other.

The first region 311 is located in the n⁻-type semiconductor part 301b. Similarly to the semiconductor device according to the first embodiment, the carbon concentration in the first region 311 is greater than the carbon concentration in the n-type base region 301. The first element concentration in the first region 311 is greater than the first element concentration in the n-type base region 301. The first region 311 spreads along the X-Y plane. For example, the first region 311 is located in both the element region CR and the termination region TR.

For example, the first region 311 is located at the emitter electrode 322 side. In other words, the distance D1 between the collector electrode 321 and the first region 311 is longer than the distance D2 between the emitter electrode 322 and the first region 311.

The method for identifying the first region 311 in the n-type base region 301 is similar to the method for identifying the first region 111 according to the first embodiment. Namely, the concentration profiles of carbon and the first element are obtained by analyzing the elements included in the n-type base region 301 along the Z-direction. The region in which the carbon concentration is low and the region in which the first element concentration is low are identified in the concentration profiles. The region in which the carbon concentration increases and the first element concentration increases with respect to the regions in which the concentrations are low is identified as the first region 311.

Operations of the semiconductor device 300 will now be described.

A voltage that is not less than a threshold is applied to the gate electrode 315 in a state in which a positive voltage with respect to the emitter electrode 322 is applied to the collector electrode 321. A channel (an inversion layer) is thereby formed in the p-type semiconductor part 302a. Electrons flow from the emitter region 304 to the n-type semiconductor part 301b via the channel; and the holes flow from the collector region 303 toward the n⁻-type semiconductor part 301b. The density of the carriers accumulated in the n-type semiconductor part 301b increases, and conductivity modulation occurs. The electrical resistance of the n⁻-type semiconductor part 301b is greatly reduced thereby, and the IGBT region R1 is set to the on-state. Subsequently, when the voltage applied to the gate electrode 315 drops below the threshold, the channel in the p-type semiconductor part 302a disappears, and the IGBT region R1 is switched to the off-state.

After the IGBT region R1 is switched to the off-state, the electrons that accumulated in the n-type semiconductor part 301b are discharged to the collector electrode 321 via the collector region 303. The holes are discharged to the emitter electrode 322 via the p-type base region 302.

For example, a bridge circuit is configured using multiple semiconductor devices 300. When one semiconductor device 300 is switched from the on-state to the off-state, the inductance component of the bridge circuit applies an induced electromotive force to the emitter electrode 322 of another semiconductor device 300. As a result, the diode region R2 of the other semiconductor device 300 operates. Holes flow from the anode region 306 toward the n-type semiconductor part 301b; and electrons flow from the cathode region 305 toward the n⁻-type semiconductor part 301b. The diode region R2 functions as a freewheeling diode (FWD).

Examples of the materials of the components will now be described.

The n-type base region 301, the p-type base region 302, the collector region 303, the emitter region 304, the cathode region 305, and the anode region 306 include silicon, silicon carbide, gallium nitride, or gallium arsenide as a semiconductor material. Boron can be used as a p-type impurity. The gate electrode 315 and the conductive part 316 include polysilicon. The gate insulating layer 315a, the insulating layer 316a, and the insulating layer 317 include insulating materials such as silicon oxide, silicon nitride, etc. The collector electrode 321, the emitter electrode 322, the gate pad 323, and the gate wiring part 323a include metals such as titanium, aluminum, etc.

According to the third embodiment, the first region 311 is located in the diode region R2 of the semiconductor device 300. Therefore, similarly to the first embodiment, when the diode region R2 operates, the switching loss can be reduced while suppressing the increase of the on-resistance.

The first region 311 also may be located in the IGBT region R1, or may be located only in the diode region R2 as shown in FIG. 19. More favorably, the first region 311 is located in only the diode region R2. In other words, in the IGBT region R1, a portion of the n-type base region 301 is located at the height at which the first region 311 is located. The carbon concentration of the portion of the n-type base region 301 of the IGBT region R1 is less than the carbon concentration of the first region 311 of the diode region R2. The first element concentration of the portion of the n-type base region 301 of the IGBT region R1 is less than the first element concentration of the first region 311 of the diode region R2.

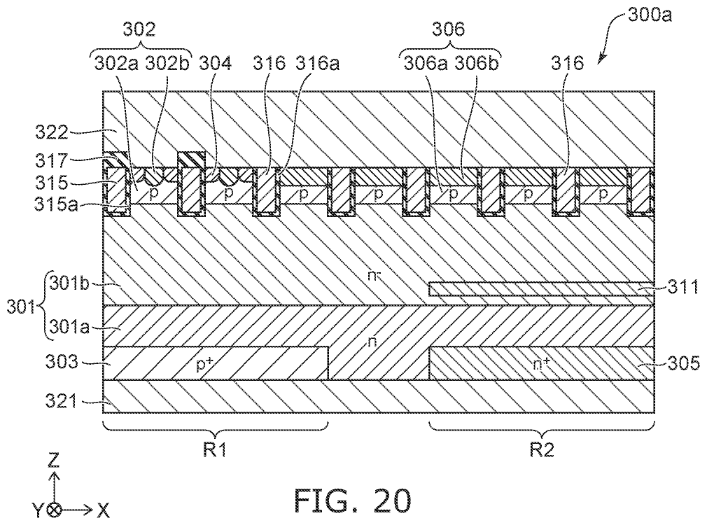

FIGS. 20 to 22 are cross-sectional views showing portions of semiconductor devices according to modifications of the third embodiment.

The structures of the modifications of the first embodiment are applicable to the semiconductor device according to the third embodiment. For example, as in a semiconductor device 300a shown in FIG. 20, the first region 311 may be located at the collector electrode 321 side. The period in which the recovery current Iᵣᵣ flowing through the diode region R2 attenuates can be reduced thereby, and the switching loss can be reduced.

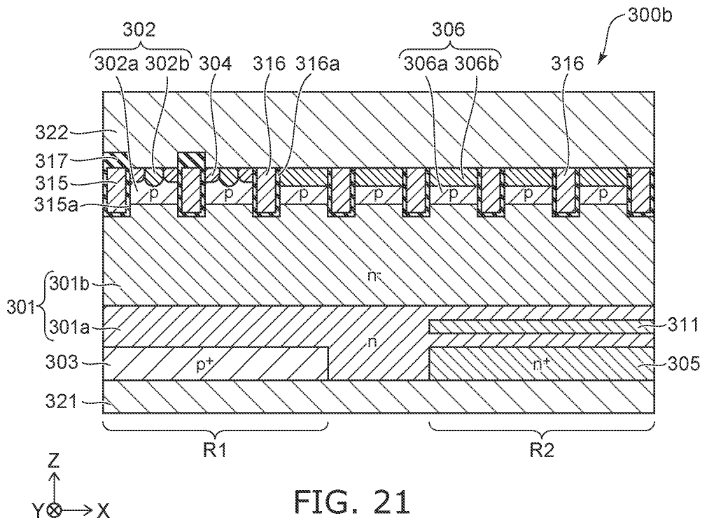

As in a semiconductor device 300b shown in FIG. 21, the first region 311 may be located in the n-type semiconductor part 301a. The leakage current in the diode region R2 can be further reduced thereby.

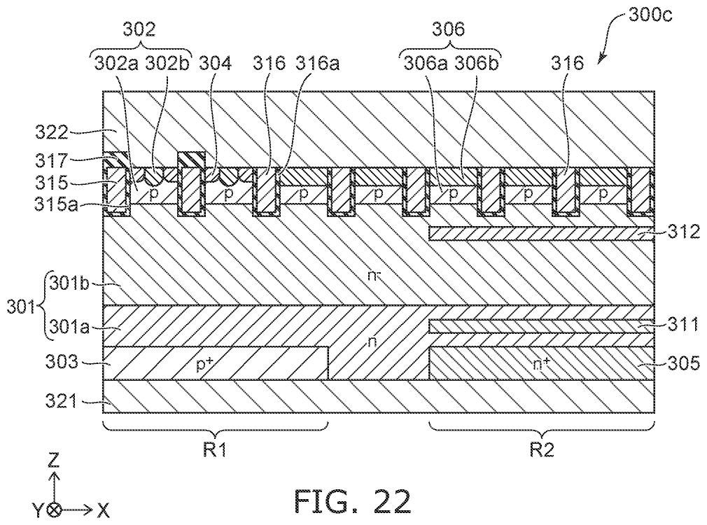

As in a semiconductor device 300c shown in FIG. 22, a second region 312 may be provided in addition to the first region 311. The switching loss of the semiconductor device 300c can be further reduced thereby.

Embodiments of the invention include the following configurations.

### (Configuration 1)

A semiconductor device, comprising:

a first electrode;

a first semiconductor region located on the first electrode, the first semiconductor region being of a first conductivity type;

a first region located in the first semiconductor region, a concentration of carbon in the first region being greater than a concentration of carbon in the first semiconductor region, a concentration of a first element in the first region being greater than a concentration of the first element in the first semiconductor region, the first element being at least one selected from the group consisting of platinum, gold, iron, copper, and nickel;

a second semiconductor region located on the first semiconductor region, the second semiconductor region being of a second conductivity type; and

a second electrode located on the second semiconductor region.

### (Configuration 2)

The device according to Configuration 1, wherein

a distance between the second electrode and the first region is less than a distance between the first electrode and the first region.

### (Configuration 3)

The device according to Configuration 1, wherein

a distance between the first electrode and the first region is less than a distance between the second electrode and the first region.

### (Configuration 4)

The device according to Configuration 3, wherein

the first semiconductor region includes a first part, and a second part located on the first part,

an n-type impurity concentration of the second part is less than an n-type impurity concentration of the first part, and

the first region is located in the first part.

### (Configuration 5)

The device according to Configuration 1, further comprising:

a second region located in the first semiconductor region,

a concentration of carbon in the second region being greater than the concentration of carbon in the first semiconductor region,

a concentration of the first element in the second region being greater than the concentration of the first element in the first semiconductor region,

a distance between the first electrode and the first region being less than a distance between the second electrode and the first region,

a distance between the second electrode and the second region being less than a distance between the first electrode and the second region.

### (Configuration 6)

The device according to any one of Configurations 1 to 5, further comprising:

a third semiconductor region located between the first electrode and the first semiconductor region, the third semiconductor region being of the second conductivity type;

a fourth semiconductor region located on the second semiconductor region, the fourth semiconductor region being of the first conductivity type; and

a gate electrode facing the second semiconductor region via a gate insulating layer in a second direction perpendicular to a first direction,

the first direction being from the first electrode toward the first semiconductor region.

### (Configuration 7)

A semiconductor device, comprising:

a first electrode;

a first semiconductor region located on the first electrode, the first semiconductor region being of a first conductivity type;

a second semiconductor region located on the first semiconductor region, the second semiconductor region being of a second conductivity type;

a first region located in the second semiconductor region, a concentration of carbon in the first region being greater than a concentration of carbon in the second semiconductor region, a concentration of a first element in the first region being greater than a concentration of the first element in the second semiconductor region, the first element being at least one selected from the group consisting of platinum, gold, iron, copper, and nickel; and

a second electrode located on the second semiconductor region.

### (Configuration 8)

A semiconductor device, comprising:

a first electrode;

a first semiconductor region located on the first electrode, the first semiconductor region being of a first conductivity type;

a second semiconductor region located on a portion of the first semiconductor region, the second semiconductor region being of a second conductivity type;

a third semiconductor region located between a portion of the first electrode and the portion of the first semiconductor region, the third semiconductor region being of the second conductivity type;

a fourth semiconductor region located on the second semiconductor region, the fourth semiconductor region being of the first conductivity type;

a gate electrode facing the second semiconductor region via a gate insulating layer in a second direction perpendicular to a first direction, the first direction being from the first electrode toward the first semiconductor region;

a fifth semiconductor region located between an other portion of the first electrode and an other portion of the first semiconductor region, the fifth semiconductor region being of the first conductivity type, the fifth semiconductor region having a higher first-conductivity-type impurity concentration than the first semiconductor region;

a sixth semiconductor region located on the other portion of the first semiconductor region, the sixth semiconductor region being of the second conductivity type;

a first region located in the other portion of the first semiconductor region, a concentration of carbon in the first region being greater than a concentration of carbon in the first semiconductor region, a concentration of a first element in the first region being greater than a concentration of the first element in the first semiconductor region, the first element being at least one selected from the group consisting of platinum, gold, iron, copper, and nickel; and

a second electrode located on the second semiconductor region, the fourth semiconductor region, and the sixth semiconductor region.

### (Configuration 9)

The device according to any one of Configurations 1 to 8, wherein

the first element is platinum.

According to the embodiments described above, the switching loss of the semiconductor device can be reduced while suppressing an increase of the leakage current or on-resistance.

In the embodiments, the relative level of impurity concentration between the semiconductor regions can be confirmed by, for example, using SCM (Scanning Capacitance Microscope). The carrier concentration in each semiconductor region can be considered equal to the concentration of impurities activated in each semiconductor region. Accordingly, the relative level of the carrier concentration between the semiconductor regions can also be confirmed using the SCM. Also, the impurity concentration in each semiconductor region can be measured by, for example, SIMS (Secondary Ion Mass Spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region located on the first electrode, the first semiconductor region being of a first conductivity type;
a first region located in the first semiconductor region, a concentration of carbon in the first region being greater than a concentration of carbon in the first semiconductor region, a concentration of a first element in the first region being greater than a concentration of the first element in the first semiconductor region, the first element being at least one selected from the group consisting of platinum, gold, iron, copper, and nickel;
a second semiconductor region located on the first semiconductor region, the second semiconductor region being of a second conductivity type; and
a second electrode located on the second semiconductor region.

2. The device according to claim 1, wherein
a distance between the second electrode and the first region is less than a distance between the first electrode and the first region.

3. The device according to claim 1, wherein
a distance between the first electrode and the first region is less than a distance between the second electrode and the first region.

4. The device according to claim 3, wherein
the first semiconductor region includes a first part, and a second part located on the first part,
an n-type impurity concentration of the second part is less than an n-type impurity concentration of the first part, and
the first region is located in the first part.

5. The device according to claim 1, further comprising:
a second region located in the first semiconductor region,
a concentration of carbon in the second region being greater than the concentration of carbon in the first semiconductor region,
a concentration of the first element in the second region being greater than the concentration of the first element in the first semiconductor region,
a distance between the first electrode and the first region being less than a distance between the second electrode and the first region,
a distance between the second electrode and the second region being less than a distance between the first electrode and the second region.

6. The device according to claim 1, further comprising:
a third semiconductor region located between the first electrode and the first semiconductor region, the third semiconductor region being of the second conductivity type;
a fourth semiconductor region located on the second semiconductor region, the fourth semiconductor region being of the first conductivity type; and
a gate electrode facing the second semiconductor region via a gate insulating layer in a second direction perpendicular to a first direction,
the first direction being from the first electrode toward the first semiconductor region.

7. The device according to claim 1, wherein
the first element is platinum.

8. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a first region located in the second semiconductor region, a concentration of carbon in the first region being greater than a concentration of carbon in the second semiconductor region, a concentration of a first element in the first region being greater than a concentration of the first element in the second semiconductor region, the first element being at least one selected from the group consisting of platinum, gold, iron, copper, and nickel; and
a second electrode located on the second semiconductor region.

9. The device according to claim 8, wherein
the first element is platinum.

10. A semiconductor device, comprising:
a first electrode;
a first semiconductor region located on the first electrode, the first semiconductor region being of a first conductivity type;
a second semiconductor region located on a portion of the first semiconductor region, the second semiconductor region being of a second conductivity type;
a third semiconductor region located between a portion of the first electrode and the portion of the first semiconductor region, the third semiconductor region being of the second conductivity type;
a fourth semiconductor region located on the second semiconductor region, the fourth semiconductor region being of the first conductivity type;
a gate electrode facing the second semiconductor region via a gate insulating layer in a second direction perpendicular to a first direction, the first direction being from the first electrode toward the first semiconductor region;
a fifth semiconductor region located between an other portion of the first electrode and an other portion of the first semiconductor region, the fifth semiconductor region being of the first conductivity type, the fifth semiconductor region having a higher first-conductivity-type impurity concentration than the first semiconductor region;
a sixth semiconductor region located on the other portion of the first semiconductor region, the sixth semiconductor region being of the second conductivity type;
a first region located in the other portion of the first semiconductor region, a concentration of carbon in the first region being greater than a concentration of carbon in the first semiconductor region, a concentration of a first element in the first region being greater than a concentration of the first element in the first semiconductor region, the first element being at least one selected from the group consisting of platinum, gold, iron, copper, and nickel; and
a second electrode located on the second semiconductor region, the fourth semiconductor region, and the sixth semiconductor region.

11. The device according to claim 10, wherein
the first element is platinum.
